(19) United States
(12) Patent Application Publication
(10) Pub. No.: US 2007/0096307 A1
(43) Pub. Date: May 3, 2007

(54) Semiconductor device

(75) Inventor: Nobuhiro Murai, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/546,997

(22) Filed: Oct. 13, 2006

(30) Foreign Application Priority Data
Oct. 14, 2005 (JP) 2005-300148

(51) Int. Cl. H01L 23/48; H01L 23/52; H01L 29/40

(52) U.S. Cl. 257/734

(57) ABSTRACT

In a semiconductor device, a occupation ratio of the surface of a resin substrate encapsulated with resin by conductor patterns provided on the same surface is set so as to be 70% or higher in order to raise the toughness of the resin substrate during heating and pressurization. Preferably, the distance between conductor patterns is set so as to be 0.15 mm or less. The resin substrate may be prevented from becoming deformed, that is, a semiconductor device in which cracking in a resin substrate, at the time of resin encapsulation, may be prohibited in a simplified manner from occurrence.

### FIELD OF THE INVENTION

This invention relates to a semiconductor device including a resin-encapsulated semiconductor element.

### BACKGROUND OF THE INVENTION

Nowadays, a semiconductor device, in which a semiconductor element, a passive element and so forth are mounted on a semiconductor substrate, and in which electrical interconnection is formed by film-shaped conductor patterns or fine metal wires, is in use in, for example, a mobile communication terminal. In such semiconductor device, the semiconductor element or the like, on the substrate, is encapsulated with a resin for assuring protection against chemical or physical actions.

FIGS. 7 and 8 are schematic views of a semiconductor device according to the related art in which a resin substrate carrying a semiconductor element thereon has its surface encapsulated with a resin. More specifically, FIG. 7 depicts a top plan view of the semiconductor device when viewed from the side of the surface of the resin substrate carrying the semiconductor element thereon, and FIG. 8 depicts a cross-sectional view taken along line VIII-VIII of FIG. 7. Meanwhile, in FIG. 7, conductor patterns 23 are shown shaded, while the encapsulating resin is not shown. In a semiconductor device 21, conductor patterns 23, 26 are arranged on upper and lower surfaces of a resin substrate 28, respectively. If the conductor patterns on the upper and lower parts of FIG. 8 are labeled 23 and 26, respectively, the upper conductor patterns 23 and the lower conductor patterns 26 are electrically connected to one another by interlayer conductor layers 27 used as coating on the inner surfaces of through-holes 25 bored through the resin substrate 28. A semiconductor element 22 is secured to the upper conductor pattern 23 with an adhesive 30, such as an electrically conductive paste, while being electrically connected to the upper conductor pattern 23 by fine metal wires 24. The semiconductor element 22 and so forth, provided on the upper conductor pattern 23, are encapsulated with a sealing resin 29.

Among the methods for resin sealing for a semiconductor device, so far known in the art, there are a transfer molding method, a potting method and a screen printing method. For example, if the transfer molding method is used for resin sealing the semiconductor device, the resin substrate is placed on a transfer molding metal mold, heated to approximately 180° C., with the substrate surface, carrying the electronic components such as the semiconductor element or a wiring for wire bonding, facing upwards. At this time, a tape (release film), with a thickness of, for example, 0.06 mm, mainly composed of a polyimide based resin, is interposed between the resin substrate and the transfer shaping mold. An encapsulating resin is injected, via a gate of the metal mold, onto a resin substrate surface, carrying a semiconductor element and so forth, and the encapsulating resin is pressurized and cured to seal the semiconductor element and so forth (see Patent Publication 1, for example).

The tape arranged between the metal mold and the resin substrate is deformed, under heating and pressurization, so as to fill the space between the metal mold and the lower conductor pattern. In this manner, the resin substrate is prevented from becoming deformed under heating and pressurization to prevent cracking in the semiconductor element or in the resin substrate.

[Patent Publication 1] JP Patent Kokai Publication No. JP-P2001-127228A

### SUMMARY OF THE DISCLOSURE

When the semiconductor device is sealed with a resin, the surface of the resin substrate, sealed with the resin, that is, the substrate surface carrying the semiconductor element, is contacted with the sealing resin, which has been heated and melted at a temperature of at least 150° C. Moreover, the surface is pressurized during molding of the sealing resin. This high temperature and the high pressure deform the resin substrate to give rise to cracking in the semiconductor element and in the surface of the resin substrate surface carrying the semiconductor element. Such cracking in the semiconductor element or in the resin substrate tends to raise problems such as lowered moisture-proofness.

As means for preventing the cracking of the resin substrate or the semiconductor element, the tape (release film), mentioned above, may be used. However, in such case, it is necessary to provide the resin sealing device, having a function of providing the tape to a space between the resin substrate and the metal mold, thus raising the equipment cost and the manufacturing cost.

Hence, it is felt to be necessary to provide simplified means for increasing the toughness of the semiconductor device itself for preventing the semiconductor device from becoming deformed at the time of resin sealing.

In one aspect, the present invention provides a semiconductor device comprising a resin substrate carrying a plurality of conductor patterns thereon, in which at least one surface of the resin substrate carries a semiconductor element, and is encapsulated with resin. The conductor patterns takes up not less than 70% of the entire surface area of the aforementioned at least one surface.

An epoxy resin, used as a material of the resin substrate, for example, has an elastic bending modulus which is lowered significantly at a temperature of 150° C. or higher. At 180° C., which is the heating temperature for transfer molding, the elastic bending modulus is at most one-half of that at 25° C. On the other hand, the Barcol hardness of the epoxy resin commences to be lowered at 100 to 150° C., as does the modulus of elasticity, with the hardness at 180° C. being one-half of that at 25° C. or even lower. Conversely, the modulus of elasticity as well as the hardness of metals, such as gold, nickel or copper, making up the conductor patterns, formed on the resin substrate, at 180° C., is scarcely changed from those at 25° C. Thus, the present invention provides a semiconductor device in which a larger proportion of the surface of the resin substrate encapsulated with a resin is covered up with conductor patterns (metallization) for preventing the resin substrate from becoming deformed under the heating and the pressurization at the time of resin encapsulation for thereby raising the toughness of the semiconductor device at the time of the heating and the pressurization.

In a preferred mode of the aforementioned first aspect, the conductor patterns include one or more dummy conductor patterns not electrically connected to other conductors. In a further preferred mode, the distance for providing for electrical insulation between the conductor patterns on the aforementioned at least one surface is 0.15 mm or less. In a further preferred mode, the thickness of the conductor patterns is at least 10 μm. In a still further preferred mode, the conductor pattern has a multi-layer structure made up a plurality of sorts of conductors. In a yet further preferred mode, the resin used for resin encapsulation is an epoxy-based resin, a polyester-based resin or a phenol-based resin.

The meritorious effects of the present invention are summarized as follows.

According to the present invention, the proportion of the conductors (metallization) in a contact area between the resin substrate and the encapsulating resin is high so that high toughness may be conferred on the resin substrate. Consequently, the resin substrate is not liable to be deformed on contact with the encapsulating resin at e.g. approximately 180° C. at the time of resin encapsulation. Moreover, since the exposed area of the resin substrate is small, that is, the gap between the neighboring conductor patterns is small, the sealing pressure applied to the softened resin substrate from the encapsulating resin acts on only a limited area, thus suppressing the entire resin substrate, inclusive of the conductor patterns, from becoming deformed. In addition, even in such a case where resin encapsulation is made at a lower temperature not higher than 150° C., it becomes possible to suppress the entire resin substrate inclusive of the conductor patterns from becoming warped due to difference between the thermal distortion between the encapsulating resin and the resin substrate occurring at the time of molding of the encapsulating resin and that occurring at the time of cooling. This prevents the resin substrate and the semiconductor element from cracking.

Moreover, according to the present invention, since the resin substrate may be prevented from becoming deformed, based on the constitution of the semiconductor substrate itself, it becomes unnecessary to provide a deformation preventive tape between the metal mold and the semiconductor device at the time of resin encapsulation. The result is that the process step and a mechanical component for supplying the tape may be dispensed with, thereby saving production costs and equipment cost. In addition, according to the present invention, since it is sufficient to change the pattern shape of the conductor patterns formed by etching or plating, depending on the particular designing, it becomes possible, by highly simplified means, to prevent the resin substrate from being deformed. Furthermore, the mounting performance of the semiconductor devices may be improved by suppressing the deformation of the semiconductor device.

### BRIEF DESCRIPTION OF THE DRAWINGS

FIG. 1 is a top plan view (exclusive of a sealing resin layer) of a semiconductor device according to a first embodiment of the present invention.

FIG. 2 is a cross-sectional view taken along line II-II of FIG. 1.

FIG. 3 is a top plan view (exclusive of a sealing resin layer) of a semiconductor device according to a second embodiment of the present invention.

FIG. 4 is a cross-sectional view taken along line IV-IV of FIG. 3.

FIG. 5 is a top plan view of a semiconductor device fabricated in an Example.

FIG. 6 is a graph showing the number of cracks produced in an Example.

FIG. 7 is a top plan view of a semiconductor device for explaining the related art.

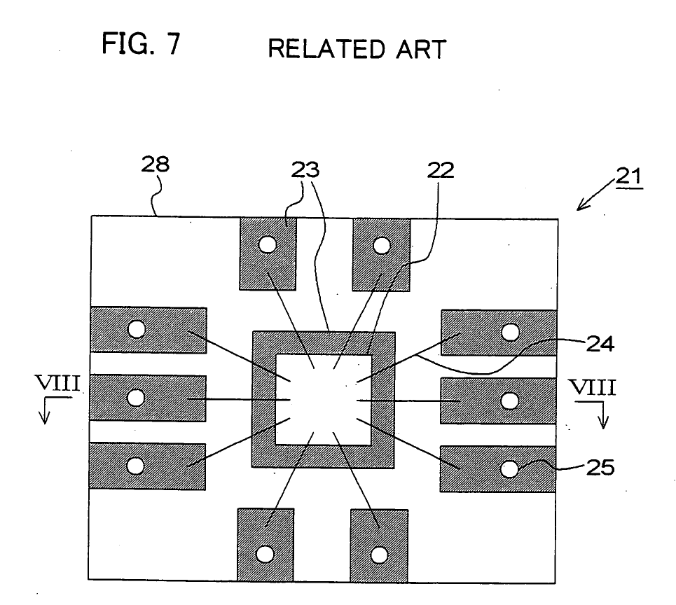

FIG. 8 is a cross-sectional view taken along line VIII-VIII of FIG. 7.

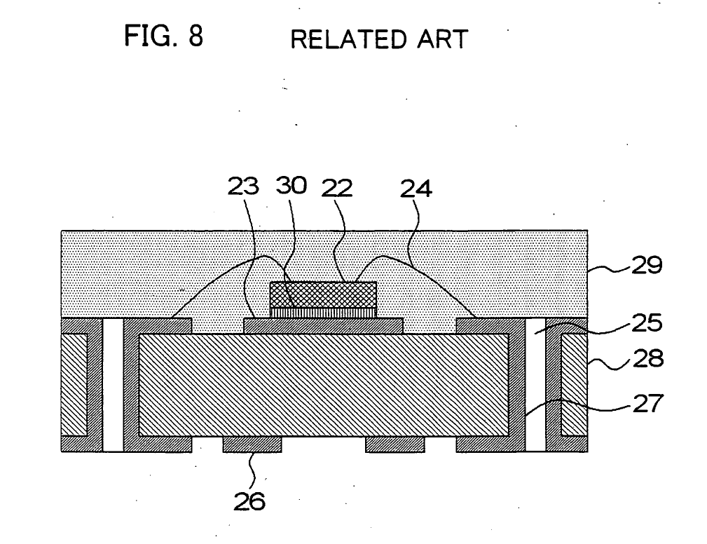

### PREFERRED EMBODIMENTS OF THE INVENTION

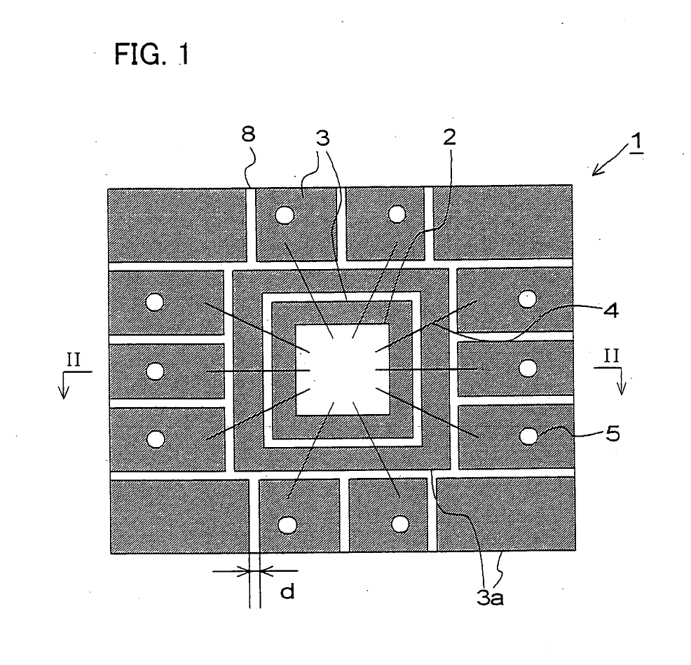

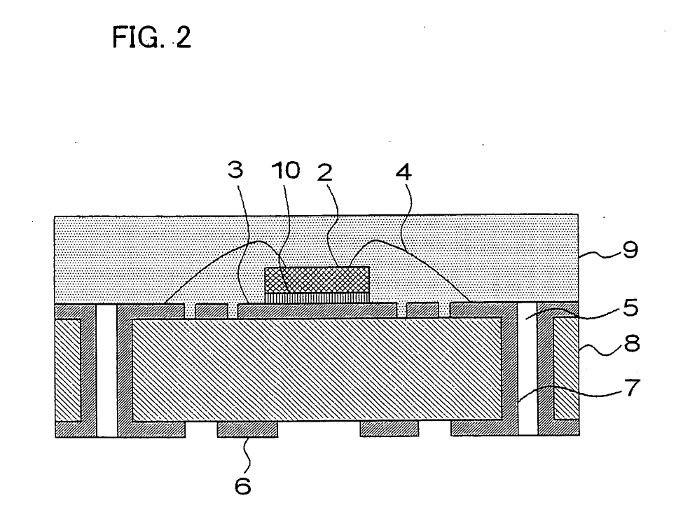

FIG. 11 depicts a top plan view of a semiconductor device according to a first embodiment of the present invention. FIG. 12 depicts a cross-sectional view taken along line II-II of FIG. 1. Meanwhile, in FIG. 1, upper conductor patterns 3 are shown shaded, while an encapsulating resin 9, shown in FIG. 2, is not shown. The semiconductor device 1 includes a resin substrate 8, upper conductor patterns 3, a semiconductor element 2, fine metal wires (bonding wires) 4, lower conductor patterns 6, through-holes 5 and sealing resin 9. The upper and lower conductor patterns 3, 6 are formed by plating or etching on the upper and lower surfaces of the resin substrate 8, respectively. Here, the conductor patterns formed on the side of the resin substrate 8 towards the sealing resin 9 are labeled the upper conductor patterns 3 and those formed on the opposite side thereof are labeled the lower conductor patterns 6. The upper and lower conductor patterns 3, 6 are electrically connected to one another by the interlayer conductor layers 7 formed on the inner surfaces of the through-holes 5 formed in turn for traversing the resin substrate 8. The semiconductor element 2 is secured to one of the upper conductor patterns 3 by an adhesive 10 containing or not containing powders of metal, such as silver. In addition, the semiconductor element 2 and the other upper conductor patterns 3 are electrically connected to one another by the fine wires (bonding wires) 4 of a metal, such as gold. The upper surface side of the resin substrate 8, that is, the upper conductor patterns 3, semiconductor element 2 and the fine metal wires 4, are encapsulated by the sealing resin 9, such as epoxy-based sealing resin.

The upper conductor patterns 3 are arranged for reducing an area of the resin substrate 8, exposed from the upper conductor patterns 3, on the side of the surface of the resin substrate 8 towards the sealing resin, to as small a value as possible, in order to prevent the resin substrate 8 from becoming deformed at the time of resin encapsulation. That is, the pattern shape of the upper conductor patterns 3 is selected to diminish the area adapted for securing the insulation between the neighboring ones of the upper conductor patterns 3. The pattern shape of the upper conductor patterns 3 is selected so that the upper conductor patterns 3 will cover at least 50%, preferably 50 to 70% and more preferably not less than 70% of the surface of the resin substrate 8.

On the other hand, an interval d between neighboring ones of the upper conductor patterns 3 is preferably not less than 0.15 mm and more preferably not less than 0.1 mm, in order to reduce the area of the exposed surface of the resin substrate 8. The thickness of the upper conductor patterns 3 is preferably not less than 10 μm and more preferably not less than 30 μm, because the thicker the thickness of the upper conductor patterns 3, the higher becomes the toughness of the semiconductor device itself.

As means for enhancing the area occupied by the upper conductor patterns 3, the area of the conductor pattern, used as electrical routing, may be increased, or there may be provided one or more dummy conductor pattern 3a not electrically connected to other conductors or to electronic components. For example, such dummy conductor pattern 3a may be formed as an area for maintaining the insulation with respect to other conductors or electronic components in corner parts of the resin substrate 8 or around the upper conductor pattern 3 on which is mounted the semiconductor element 2, as in the semiconductor device 1 shown in FIG. 1. The dummy conductor pattern 3a may be formed of the same material as the conductor patterns used as electrical routing. Or, since the dummy conductor pattern is not used as the electrical routing, it may be formed of inexpensive or hard metal.

As auxiliary measures, the lower conductor patterns 6 may also be increased in the area occupation ratio and/or in thickness, as are the upper conductor patterns 3, in order to increase the toughness of the semiconductor device 1.

The upper and lower conductor patterns 3, 6 may be formed of metal regardless of metal sorts. However, such metals as are high in electrical conductivity may, of course, be most desirable. The metals may be in the form of metals per se or metal alloys. In particular, the conductor patterns 3, 6 are formed most desirably from copper, gold, silver or nickel, or may be of a multi-layered structure including plating layers. For example, the upper and lower conductor patterns 3, 6, each including gold, nickel and copper layers deposited to thicknesses of 1 μm, 5 μm and 30 μm, respectively, when looking from the uppermost layer, may be used.

The material of the resin substrate 8 may suitably be selected, and an epoxy resin or a polyimide resin, for example, may be used. The sealing resin 9 may be an epoxy-based resin, a polyester-based resin, a phenol-based resin or a silicone-based resin.

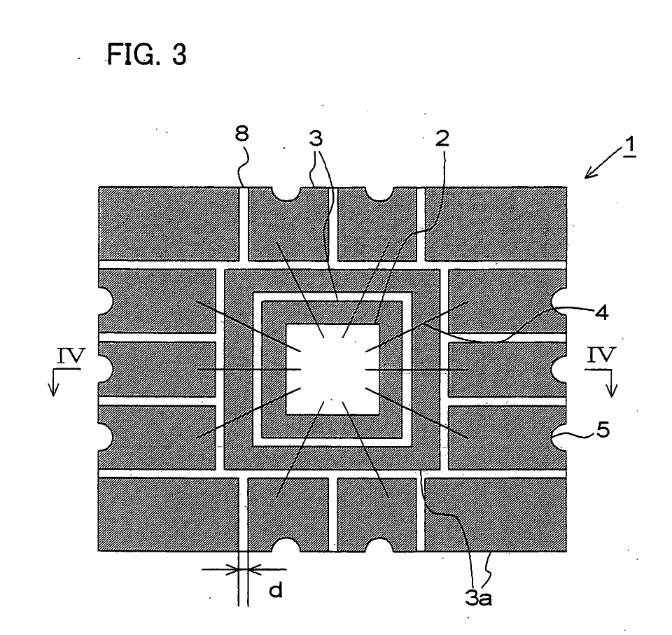

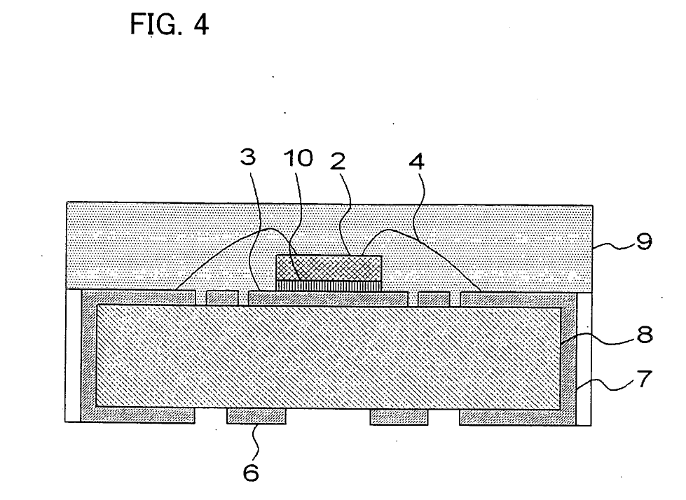

FIG. 3 shows a top plan view of a semiconductor device according to a second embodiment of the present invention. FIG. 4 depicts a cross-sectional view taken along line IV-IV of FIG. 3. In FIG. 3, the upper conductor patterns 3 are shown shaded, while the sealing resin 9 is not shown. In the semiconductor device 1 of the first embodiment, the through-holes 5 are formed for traversing the resin substrate 8. In the semiconductor device 1 of the second embodiment, the through-holes 5 are formed in the lateral sides of the resin substrate 8 so as to expose the inner surfaces of the through-holes. In the second embodiment, it is possible to check the wetting state of the solder in the lateral surfaces of the resin substrate. The configuration of the upper conductor patterns 3 is similar to that of the first embodiment.

### EXAMPLE

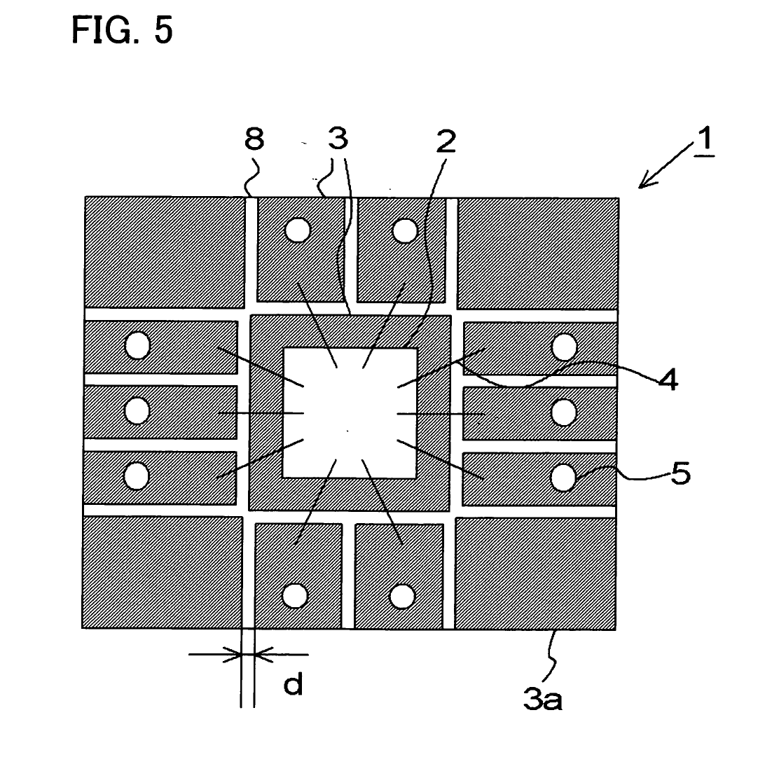

Samples of the semiconductor devices 1, having different distances d between neighboring conductor patterns of 0.075 mm, 0.10 mm, 0.15 mm, 0.20 mm, 0.25 mm, 0.30 mm, 0.35 mm and 0.375 mm, as shown in FIG. 5, were prepared and checked as to occurrence of cracking at the time of resin encapsulation in each sample of the semiconductor devices 1. The conductor patters are designed to arrange a central square pattern, corner dummy patterns 3a of elongated squares, two squares (each with a through-hole) on upper side and lower side of the figure, respectively, and three elongated patterns (each with a though-hole) on left side and right side, respectively. On a resin substrate 8 of glass epoxy, 110 μm thick, conductor patterns 3, 6, formed of copper, nickel and gold layers, were formed, and a semiconductor element 2 was mounted on an upper conductor patterns 3 (i.e., on the central pattern), using an adhesive 10, containing silver powders. The conductor patterns 3, 6 were formed of a lower layer and an upper layer. The lower layer was formed of a copper layer and was 23 μm thick and, while the upper layer was formed of nickel and gold layers, with the total thickness being 7 μm. The upper conductor patterns 3 and the lower conductor patterns 6 were electrically connected to one another with the fine metal wires 4, while the upper conductor patterns 3 and the lower conductor patterns 6 were electrically connected to one another via through-holes 5. The dummy conductor patterns 3a, not electrically connected to the semiconductor element 2 or the like and which simply cover the surface of the resin substrate 8, were formed at the corners of the resin substrate 8. Finally, the surface side of the resin substrate, carrying the semiconductor element 2, was encapsulated with the epoxy resin. This resin encapsulation was carried out by a transfer molding method, without using the tape, under the conditions of a temperature of 175° C., a pressure of approximately 9.8×10⁶ Pa (about 100 kgf/cm²) and a encapsulation residence time of about 2 min.

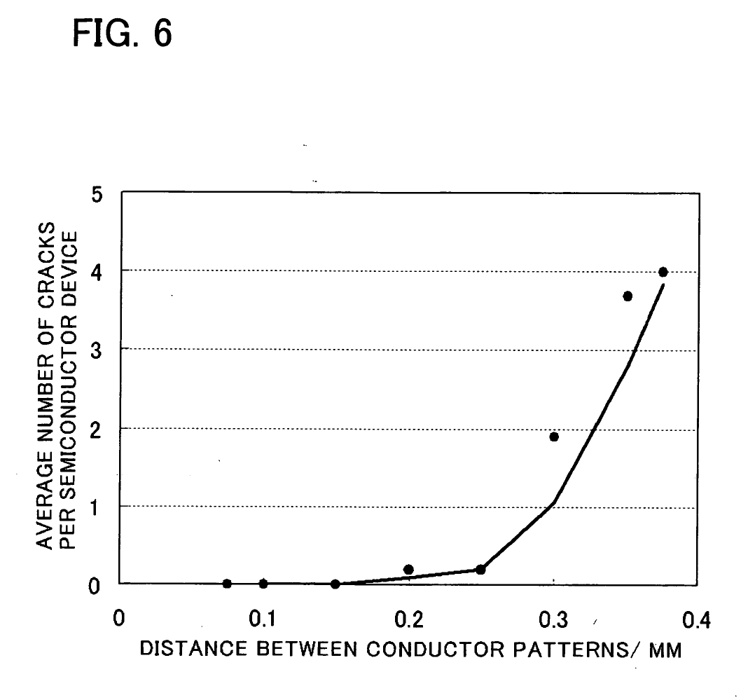

The graph showing the relationship between the average number of cracks per semiconductor device, produced in the semiconductor element 2 at the time of resin encapsulation, and the distance d between the neighboring ones of the upper conductor patterns 3, is shown in FIG. 6. The cracks were produced beginning from the upper surface towards the lower surface of the semiconductor element 2. It is seen from FIG. 6 that, when the distance between the neighboring ones of the upper conductor patterns 3 exceeds 0.2 mm, with the occupation ratio of the upper conductor patterns 3 being less than 50%, the number of cracks is increased. No cracks were seen to have been produced for the distance d between the neighboring ones of the upper conductor patterns 3 at 1.5 mm or less corresponding to the resin substrate surface occupation ratio of the upper conductor patterns 3 being not less than approximately 70%. From this it may be seen that the distance between the conductor patterns, that is, the resin substrate surface occupation ratio of the conductor patterns, seriously affects the cracking at the time of resin encapsulation, and that, by adjusting the distance of the conductor patterns, that is, the resin substrate surface occupation ratio of the conductor patterns, cracking may be prevented from occurrence without using the tape.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
a resin substrate carrying a plurality of conductor patterns thereon, at least one surface of said resin substrate carrying a semiconductor element, said at least one surface being encapsulated with a resin; wherein
said conductor patterns occupy not less than 70% of the surface area of said at least one surface.

2. The semiconductor device according to claim 1 wherein said conductor patterns include one or more dummy conductor patterns not electrically connected to other conductors.

3. The semiconductor device according to claim 1 wherein the distance for providing for electrical insulation between said conductor patterns on said at least one surface is 0.15 mm or less.

4. The semiconductor device according to claim 1 wherein said conductor patterns have a thickness of at least 10 μm.

5. The semiconductor device according to claim 1 wherein said conductor patterns have a multi-layer structure made up of a plurality of sorts of conductors.

6. The semiconductor device according to claim 1 wherein the resin used for resin encapsulation is selected from the group consisting of an epoxy-based resin, a polyester-based resin and a phenol-based resin.

7. The semiconductor device according to claim 2 wherein said conductor patterns have a multi-layer structure made up of a plurality of sorts of conductors.

8. The semiconductor device according to claim 2 wherein the resin used for resin encapsulation is selected from the group consisting of an epoxy-based resin, a polyester-based resin and a phenol-based resin.

9. A semiconductor device comprising:
a resin substrate carrying a plurality of conductor patterns thereon, at least one surface of said resin substrate carrying a semiconductor element, said at least one surface being encapsulated with a resin; wherein
said conductor patterns occupy not less than 70% of the entire surface area of said at least one surface, and
the distance between said neighboring conductor patterns on said at least one surface is adapted so as to suppress occurrence of cracking during encapsulation by a sealing resin without an intervening tape.
